(19) United States
(12) Patent Application Publication
(10) Pub. No.: US 2025/0239834 A1
(43) Pub. Date: Jul. 24, 2025

(54) SURFACE EMITTING ELEMENT, LIGHT-EMITTING DEVICE, AND METHOD OF MANUFACTURING SURFACE EMITTING ELEMENT

(71) Applicant: SONY GROUP CORPORATION, TOKYO (JP)

(72) Inventors: TATSUROU SATOU, TOKYO (JP); HIDEKAZU KAWANISHI, TOKYO (JP); RINTARO KODA, TOKYO (JP); TATSUSHI HAMAGUCHI, TOKYO (JP); EIJI NAKAYAMA, KUMAMOTO (JP); YUKIO HOSHINA, KUMAMOTO (JP); KENTARO HAYASHI, TOKYO (JP); JARED KEARNS, TOKYO (JP)

(21) Appl. No.: 18/685,574

(22) PCT Filed: Mar. 9, 2022
(86) PCT No.: PCT/JP2022/010414

§ 371 Date: Feb. 22, 2024

(30) Foreign Application Priority Data
Sep. 8, 2021 (JP) 2021-145937

(51) Int. Cl. H01S 5/10; H01S 5/183; H01S 5/30

(52) U.S. Cl. CPC H01S 5/1053; H01S 5/18361; H01S 5/3013

(57) ABSTRACT

A surface emitting element includes: a substrate having a first surface and a second surface opposed to the first surface; an epitaxial growth layer including a first semiconductor layer that is of a first electrically conductive type, an active layer, and a second semiconductor layer that is of a second electrically conductive type sequentially stacked on the second surface by epitaxial growth, the epitaxial growth layer having distributions in thickness and resonator length; an electrode electrically coupled to the first semiconductor layer; a current injection region formed on a surface of the second semiconductor layer on side opposite to the substrate, the current injection region being electrically coupled to the second semiconductor layer and having light transparency; a first reflective layer formed on the first surface at a position corresponding to a predetermined thickness of the epitaxial growth layer, the first reflective layer including a curve mirror structure; and a second reflective layer formed on a surface of the current injection region on side opposite to the second semiconductor layer.

### TECHNICAL FIELD

The present disclosure relates to a surface emitting element, a light-emitting device, and a method of manufacturing a surface emitting element.

### BACKGROUND ART

For example, NPTL 1 discloses a GaN-based vertical resonator surface emitting laser (VCSEL: Vertical Cavity Surface Emitting Laser). In the VCSEL, each of an n-type GaN layer, an active layer, and a p-type GaN layer is stacked on an n-type GaN substrate. All of the n-type GaN layer, the active layer, and the p-type GaN layer are formed into a film by epitaxial growth.

An n-side reflective layer (DBR: Distributed Bragg Reflector) is formed under the n-type GaN substrate. A p-side reflective layer (DBR) is formed on the p-type GaN layer. Additionally, an n-side metal electrode and a p-side metal electrode are electrically coupled to the n-type GaN layer and the p-type GaN layer, respectively.

### CITATION LIST

### Patent Literature

NPTL 1: SCIENTIFIC REPORTS| (2018) 8:10350|DOI:10.1038/s41598-018-28418-6

### SUMMARY OF THE INVENTION

In manufacturing a VCSEL, an epitaxial growth layer is formed with a uniform thickness within a plane surface of a GaN wafer. An offset of the thickness of the epitaxial growth layer from a set value causes a change in threshold current density, which leads to deterioration of the characteristics of the VCSEL.

Meanwhile, in the VCSEL, an inclination of a reflective layer has a large influence on the characteristics. For example, if the reflective layer is inclined slightly at 0.001 degrees, an optical loss including a diffraction loss will noticeably increase.

Accordingly, it is desirable to effectively reduce or prevent an optical loss including a diffraction loss in the VCSEL.

A surface emitting element according to a first embodiment of the present disclosure includes: a substrate having a first surface and a second surface opposed to the first surface; an epitaxial growth layer including a first semiconductor layer that is of a first electrically conductive type, an active layer, and a second semiconductor layer that is of a second electrically conductive type sequentially stacked on the second surface by epitaxial growth, the epitaxial growth layer having distributions in thickness and resonator length; an electrode electrically coupled to the first semiconductor layer; a current injection region formed on a surface of the second semiconductor layer on side opposite to the substrate, the current injection region being electrically coupled to the second semiconductor layer and having light transparency; a first reflective layer formed on the first surface at a position corresponding to a predetermined thickness of the epitaxial growth layer, the first reflective layer including a curve mirror structure; and a second reflective layer formed on a surface of the current injection region on side opposite to the second semiconductor layer.

A light-emitting device according to a second embodiment of the present disclosure includes a plurality of surface emitting elements arranged. The surface emitting elements each include: a substrate having a first surface and a second surface opposed to the first surface; an epitaxial growth layer including a first semiconductor layer that is of a first electrically conductive type, an active layer, and a second semiconductor layer that is of a second electrically conductive type sequentially stacked on the second surface by epitaxial growth, the epitaxial growth layer having distributions in thickness and resonator length; an electrode electrically coupled to the first semiconductor layer; a current injection region formed on a surface of the second semiconductor layer on side opposite to the substrate, the current injection region being electrically coupled to the second semiconductor layer and having light transparency; a first reflective layer formed on the first surface at a position corresponding to a predetermined thickness of the epitaxial growth layer, the first reflective layer including a curve mirror structure; and a second reflective layer formed on a surface of the current injection region on side opposite to the second semiconductor layer.

A method of manufacturing a surface emitting element according to a third embodiment of the present disclosure includes: forming an epitaxial growth layer having distributions in thickness and resonator length by sequentially stacking, on a second surface, opposed to a first surface, of a substrate, a first semiconductor layer that is of a first electrically conductive type, an active layer, and a second semiconductor layer that is of a second electrically conductive type by epitaxial growth; forming an electrode electrically coupled to the first semiconductor layer; forming a current injection region on a surface of the second semiconductor layer on side opposite to the substrate, the current injection region being electrically coupled to the second semiconductor layer and having light transparency; forming a second reflective layer on a surface of the current injection region on side opposite to the second semiconductor layer; and measuring a thickness of the epitaxial growth layer and forming a first reflective layer including a curve mirror structure at a predetermined position in the first surface.

### BRIEF DESCRIPTION OF DRAWING

FIG. 1 is a cross-sectional view of a relevant part of a surface emitting element and a light-emitting device according to a first embodiment of the present disclosure.

FIG. 2 is a schematic cross-sectional view of an epitaxial growth layer formed into a film on a substrate (here, a wafer) during a process of manufacturing the surface emitting element illustrated in FIG. 1.

FIG. 3 is a perspective view of a relevant part, assisting in explaining a correspondence relationship between a part of the epitaxial growth layer and a first reflective layer, the part of the epitaxial growth layer being taken as the surface emitting element from the substrate illustrated in FIG. 2.

FIG. 4 is a cross-sectional view of the relevant part, assisting in explaining the correspondence relationship between the part of the epitaxial growth layer and the first reflective layer illustrated in FIG. 3.

FIG. 5 is a diagram illustrating a relationship between an offset amount of a thickness of the epitaxial growth layer from a set value and a threshold current density in the surface emitting element illustrated in FIG. 1.

FIG. 6 is a flowchart of assistance in explaining an exemplary method of manufacturing the surface emitting element according to the first embodiment.

FIG. 7 is a cross-sectional view corresponding to FIG. 4 of a relevant part of a surface emitting element and a light-emitting device according to a second embodiment of the present disclosure.

FIG. 8 is a cross-sectional view corresponding to FIG. 4 of a relevant part of a surface emitting element and a light-emitting device according to a third embodiment of the present disclosure.

FIG. 9 is a process cross-sectional view, assisting in explaining a method of manufacturing an epitaxial growth layer in a surface emitting element and a light-emitting device according to a fourth embodiment of the present disclosure.

FIG. 10 is a process cross-sectional view corresponding to FIG. 9, assisting in explaining a method of manufacturing an epitaxial growth layer in a surface emitting element and a light-emitting device according to a fifth embodiment of the present disclosure.

FIG. 11 is a process cross-sectional view corresponding to FIG. 9, assisting in explaining a method of manufacturing an epitaxial growth layer in a surface emitting element and a light-emitting device according to a sixth embodiment of the present disclosure.

FIG. 12 is a process cross-sectional view corresponding to FIG. 9, assisting in explaining a method of manufacturing an epitaxial growth layer in a surface emitting element and a light-emitting device according to a seventh embodiment of the present disclosure.

FIG. 13 is a process cross-sectional view corresponding to FIG. 9, assisting in explaining a method of manufacturing an epitaxial growth layer in a surface emitting element and a light-emitting device according to an eighth embodiment of the present disclosure.

FIG. 14A is a schematic plan diagram of assistance in explaining an arrangement form of an insulating body within a plane surface of a substrate (here, a wafer) illustrated in FIG. 13.

FIG. 14B is a schematic plan diagram corresponding to FIG. 14A, assisting in explaining an arrangement form of the insulating body according to a first modification example of the eighth embodiment.

FIG. 14C is a schematic plan diagram corresponding to FIG. 14A, assisting in explaining an arrangement form of the insulating body according to a second modification example of the eighth embodiment.

FIG. 14D is a schematic plan diagram corresponding to FIG. 14A, assisting in explaining an arrangement form of the insulating body according to a third modification example of the eighth embodiment.

FIG. 14E is a schematic plan diagram corresponding to FIG. 14A, assisting in explaining an arrangement form of the insulating body according to a fourth modification example of the eighth embodiment.

FIG. 14F is a schematic plan diagram corresponding to FIG. 14A, assisting in explaining an arrangement form of the insulating body according to a fifth modification example of the eighth embodiment.

FIG. 15 is a process cross-sectional view corresponding to FIG. 9, assisting in explaining a method of manufacturing an epitaxial growth layer in a surface emitting element and a light-emitting device according to a ninth embodiment of the present disclosure.

### MODES FOR CARRYING OUT THE INVENTION

In the following, some embodiments of the present disclosure are described in detail with reference to the drawings. It is to be noted that description is made in the following order.

### 1. First Embodiment

In the first embodiment, description will be made on an example where the present technology is applied to a surface emitting element and a light-emitting device. Here, description will be made on a basic structure and a manufacturing process of the surface emitting element.

### 2. Second Embodiment

The second embodiment is an example where the present technology is applied and description will be made on a first example where a structure of an epitaxial growth layer in the surface emitting element and the light-emitting device according to the first embodiment is altered.

### 3. Third Embodiment

The third embodiment is an example where the present technology is applied and description will be made on a second example where the structure of the epitaxial growth layer in the surface emitting element and the light-emitting device according to the first embodiment is altered.

### 4. Fourth Embodiment

The fourth embodiment is an example where the present technology is applied and description will be made on a first example of a specific method of manufacturing the epitaxial growth layer in the surface emitting element and the light-emitting device according to the first embodiment.

### 5. Fifth Embodiment

The fifth embodiment is an example where the present technology is applied and description will be made on a second example of the specific method of manufacturing the epitaxial growth layer in the surface emitting element and the light-emitting device according to the first embodiment.

### 6. Sixth Embodiment

The sixth embodiment is an example where the present technology is applied and description will be made on a third example of the specific method of manufacturing the epitaxial growth layer in the surface emitting element and the light-emitting device according to the first embodiment.

### 7. Seventh Embodiment

The seventh embodiment is an example where the present technology is applied and description will be made on a fourth example of the specific method of manufacturing the epitaxial growth layer in the surface emitting element and the light-emitting device according to the first embodiment.

### 8. Eighth Embodiment

The eighth embodiment is an example where the present technology is applied and description will be made on a fifth example of the specific method of manufacturing the epitaxial growth layer in the surface emitting element and the light-emitting device according to the first embodiment. Here, description will also be made on a plurality of modification examples.

### 9. Ninth Embodiment

The ninth embodiment is an example where the present technology is applied and description will be made on a sixth example of the specific method of manufacturing the epitaxial growth layer in the surface emitting element and the light-emitting device according to the first embodiment.

### 10. Other Embodiments

### 1. First Embodiment

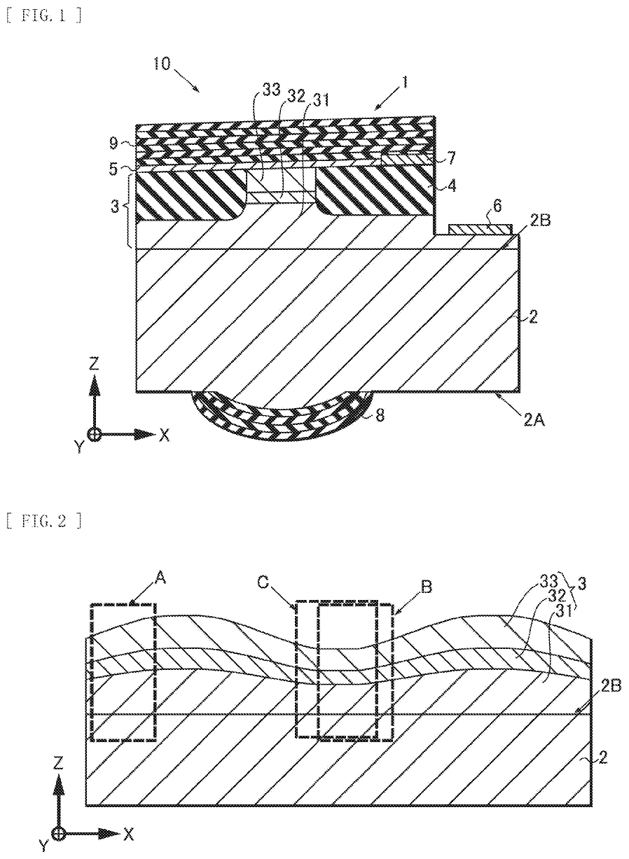

Description will be made on a surface emitting element 1 and a light-emitting device 10 according to a first embodiment of the present disclosure with use of FIG. 1 to FIG. 6.

Here, in the drawings, an illustrated arrow-X direction indicates one planar direction of the surface emitting element 1 placed on a plane surface as appropriate. An arrow-Y direction indicates another planar direction perpendicular to the arrow-X direction. Additionally, an arrow-Z direction indicates an upward direction perpendicular to the arrow-X direction and the arrow-Y direction. In short, the arrow-X direction, the arrow-Y direction, and the arrow-Z direction correspond precisely to an X-axis direction, a Y-axis direction, and a Z-axis direction of a three-dimensional coordinate system, respectively.

It should be noted that these directions are illustrated for assistance in understanding the explanation and not intended to limit directions of the present technology.

### [Configuration of Surface Emitting Element 1]

### (1) Schematic Overall Configuration of Surface Emitting Element 1

FIG. 1 illustrates an example of a vertical cross-sectional configuration of the surface emitting element 1.

The surface emitting element 1 according to the first embodiment is configured as a VCSEL. The surface emitting element 1 includes, as main components, a substrate 2, an epitaxial growth layer 3, a first reflective layer 8, and a second reflective layer 9. The epitaxial growth layer 3 includes a first semiconductor layer 31, an active layer 32, and a second semiconductor layer 33.

The surface emitting element 1 also has a narrowing region 4 and a current injection region 5. Moreover, a first electrode 6 and a second electrode 7 are further formed in the surface emitting element 1.

### (2) Configuration of Substrate 2

In the first embodiment, the surface emitting element 1 is configured as, for example, a GaN-based VCSEL. Thus, a GaN substrate that is of a first electrically conductive type is used as the substrate 2. For example, the first electrically conductive type is an “n-type” and the substrate 2 is an n-type GaN substrate. A lower surface of the substrate 2 in the drawing is a first surface 2A. An upper surface of the substrate 2 opposed to the first surface 2A is a second surface 2B.

Here, in manufacturing the surface emitting element 1, the substrate 2 is a “wafer” during simultaneous manufacturing of a plurality of surface emitting elements 1. Additionally, in manufacturing the surface emitting element 1, the substrate 2 is a “chip (or die)” after the wafer is diced through a dicing process.

### (3) Configuration of First Semiconductor Layer 31 of Epitaxial Growth Layer 3

The first semiconductor layer 31 of the epitaxial growth layer 3 is stacked on the second surface 2B of the substrate 2 by epitaxial growth. The second surface 2B is a plane surface extending in the arrow-X direction and the arrow-Y direction. The first semiconductor layer 31 is formed into a film toward the arrow-Z direction on the second surface 2B as viewed from a plane direction of the second surface 2B (hereinafter, simply referred to as “in side view”).

The first semiconductor layer 31 is used as a cladding layer. The first semiconductor layer 31 includes, for example, a GaN that is of a first electrically conductive type (an n-type GaN). The first semiconductor layer 31 is formed with a thickness, for example, in a range from 100 nm to 10 μm both inclusive.

### (4) Configuration of Active Layer 32 of Epitaxial Growth Layer 3

The active layer 32 is stacked on the first semiconductor layer 31 by epitaxial growth. The active layer 32 is formed into a film on a surface of the first semiconductor layer 31 on side opposite to the substrate 2. The active layer 32 is a light-emitting layer. The active layer 32 has a structure where a plurality of barrier layers and a plurality of quantum well layers are alternately stacked. The active layer 32 includes, for example, GaInN as a main composition. The active layer 32 is formed with a thickness, for example, in a range from 1 nm to 50 nm both inclusive.

Additionally, the active layer 32 may include quantum wires or quantum dots in place of the quantum well layers. Further, the active layer 32 may be configured as a distortion compensation quantum well.

### (5) Configuration of Second Semiconductor Layer 33 of Epitaxial Growth Layer 3

The second semiconductor layer 33 of the epitaxial growth layer 3 is stacked on the active layer 32 by epitaxial growth. The second semiconductor layer 33 is formed into a film on a surface of the active layer 32 on side opposite to the first semiconductor layer 31.

The second semiconductor layer 33 is used as a cladding layer. The second semiconductor layer 33 includes, for example, a GaN that is of a second electrically conductive type. The second electrically conductive type is a “p-type”, that is, the opposite electrically conductive type to the first electrically conductive type. The second semiconductor layer 33 is thus a p-type GaN. The second semiconductor layer 33 is formed with a thickness, for example, in a range from 10 nm to 250 nm both inclusive.

### (6) Configuration of Epitaxial Growth Layer 3

In the first embodiment, the epitaxial growth layer 3 includes a uniform stacked structure within the second surface 2B of the substrate 2 and is formed with a non-uniform thickness within the second surface 2B. In short, the surface emitting element 1 has a distribution where the thickness of the epitaxial growth layer 3 differs within the second surface 2B and, further, has a distribution where a length of a resonator length differs with the distribution in thickness.

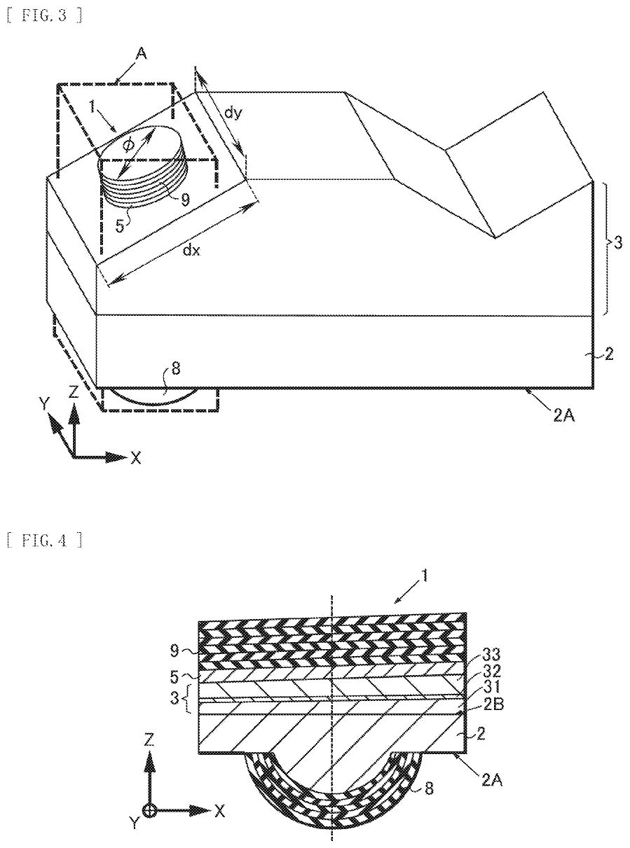

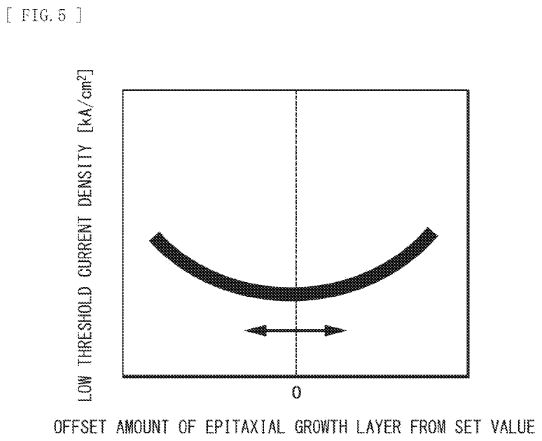

FIG. 2 schematically illustrates a vertical cross-sectional structure of the substrate 2 in a wafer state during a process of manufacturing the surface emitting element 1. FIG. 3 schematically illustrates a three-dimensional structure of the substrate 2 in the wafer state illustrated in FIG. 2. Moreover, FIG. 4 schematically illustrates a vertical cross-sectional structure of the surface emitting element 1 manufactured from the epitaxial growth layer 3 in a region labeled with a reference sign A in FIG. 2 and FIG. 3.

As illustrated in FIG. 2 and FIG. 3, during the process of manufacturing the surface emitting element 1, the epitaxial growth layer 3 for manufacturing a plurality of surface emitting elements 1 is formed on the single substrate 2 in the wafer state. Here, the epitaxial growth layer 3 formed within a plane of the second surface 2B of the substrate (the wafer) 2 has a non-uniform thickness.

Each of the plurality of layers constituting the epitaxial growth layer 3, i.e., the first semiconductor layer 31, the active layer 32, and the second semiconductor layer 33, is formed with a non-uniform thickness and the epitaxial growth layer 3 is formed with a non-uniform thickness as a whole. In other words, an interface of the stacked structure of the epitaxial growth layer 3 is formed in a linear shape with an inclination relative to the second surface 2B in side view. In detail, as illustrated especially in FIG. 1 and FIG. 4, an interface between the first semiconductor layer 31 and the active layer 32 and an interface between the active layer 32 and the second semiconductor layer 33 are each formed in a linear shape with an inclination relative to the second surface 2B.

It should be noted that at least one single layer of the first semiconductor layer 31, the active layer 32, or the second semiconductor layer 33 may be formed with a non-uniform thickness, causing the epitaxial growth layer 3 to be formed with a non-uniform thickness as a whole.

An epitaxial growth layer 3 in the region surrounded by a broken line and labeled with the reference sign A is selected from within the epitaxial growth layer 3 with the non-uniform thickness and the surface emitting element 1 illustrated in FIG. 4 includes the selected epitaxial growth layer 3. In the region surrounded by the broken line and labelled with the reference sign A, the epitaxial growth layer 3 is formed with a thickness of a predetermined set value. The thickness of the set value will be described later.

Additionally, in the first embodiment, a range dx where an amount of change in the thickness of the epitaxial growth layer 3 constantly increases in the arrow-X direction is selected and the selected epitaxial growth layer 3 is used to manufacture the surface emitting element 1 as illustrated in FIG. 3. Here, a range dy where no amount of change in the thickness of the epitaxial growth layer 3 in the arrow-Y direction is present is selected. In short, the surface emitting element 1 is constructed within the range dx and the range dy of the epitaxial growth layer 3 as viewed from the arrow-Z direction (hereinafter, simply referred to as “in plan view”). For example, in plan view, when the second reflective layer 9 is formed in a circular shape with a diameter cp, the second reflective layer 9 is formed within the range dx and the range dy of the epitaxial growth layer 3 (φ≤dx×dy).

It should be noted that the surface emitting element 1 may be manufactured in the range dx where the amount of change in the thickness of the epitaxial growth layer 3 constantly decreases. Further, the surface emitting elements 1 may be manufactured in the range dx where the amount of change in the thickness of the epitaxial growth layer 3 constantly increases and the range dy where the amount of change in the thickness of the epitaxial growth layer 3 constantly increases or decreases. Likewise, the surface emitting elements 1 may be manufactured in the range dx where the amount of change in the thickness of the epitaxial growth layer 3 constantly decreases and the range dy where the amount of change in the thickness of the epitaxial growth layer 3 constantly increases or decreases.

FIG. 5 illustrates a relationship between an offset amount of the thickness of the epitaxial growth layer 3 and a low threshold current density. The horizontal axis represents the offset amount of the thickness of the epitaxial growth layer 3. The vertical axis represents the low threshold current density (Jₜₕ [kA/cm²]).

At a middle of the horizontal axis, the offset amount is “0” with respect to the predetermined set value of the thickness of the epitaxial growth layer 3. At the offset amount “0”, the low threshold current density reaches a minimum value. As the thickness of the epitaxial growth layer 3 is offset toward a direction to increase (a rightward direction) with respect to the offset amount “0”, the low threshold current density increases. Likewise, as the thickness of the epitaxial growth layer 3 is offset toward a direction to decrease (a leftward direction) with respect to the offset amount “0”, the low threshold current density increases.

A difference in optical film thickness of the epitaxial growth layer 3 corresponds to two or more longitudinal mode spacings where an oscillation wavelength of the surface emitting element 1 is offset.

For example, in a case where the resonator length of the surface emitting element 1 is set, for example, in a range from 10 μm to 20 μm both inclusive, the longitudinal mode spacing falls within a range from 1 nm to 4 nm both inclusive, approximately. Assuming that the resonator length is 20 μm, a longitudinal mode spacing of 1 nm, approximately, provides a breadth of variation in the thickness of the epitaxial growth layer 3 corresponding to 1 nm. A thickness comparable to the offset amount “0” of the epitaxial growth layer 3 is present within a range of the breadth of variation.

Additionally, when a resonator includes a material with a refractive index of “2”, the breadth of variation in the thickness of the epitaxial growth layer 3 is 0.5 nm.

Therefore, as long as such a difference in optical film thickness is set in the epitaxial growth layer 3, it is possible to select the thickness of the epitaxial growth layer 3 causing the low threshold current density to reach the minimum value.

Further, as long as it is possible to generate a difference in optical film thickness in a severalfold to several dozen times larger range in the epitaxial growth layer 3, the thickness of the epitaxial growth layer 3 causing the low threshold current density to reach the minimum is reliably selectable.

Here, the epitaxial growth layer 3 is not limited to GaN. The epitaxial growth layer 3 may include at least one or more materials selected from among InGaN, AlGaN, AlGaInN, GaAs, AlGaAs, AlAs, InGaAs, AlInGaP, InGaP, InP, InAlAs, AlInGaAs, AlGaAsP, InGaAs, InGaSb, and AlGaSb.

### (7) Configuration of Narrowing Region 4

Referring back to FIG. 1, the narrowing region 4 is formed within the epitaxial growth layer 3 around the active layer 32. Here, the narrowing region 4 is configured as a current narrowing region and a light trapping region. In the first embodiment, the narrowing region 4 is formed by implanting, for example, boron around the active layer 32 by an ion implantation method for inactivation.

It should be noted that the narrowing region 4 may include an insulating body or a dielectric.

### (8) Configuration of Current Injection Region 5

The current injection region 5 is formed on the second semiconductor layer 33. The current injection region 5 is stacked on a surface of the second semiconductor layer 33 on side opposite to the substrate 2. The current injection region 5 is electrically coupled to the second semiconductor layer 33. The current injection region 5 is formed within a region circumferentially surrounded by the narrowing region 4 at least on the second semiconductor layer 33 in plan view and, further, extends all over the narrowing region 4.

The current injection region 5 has electrical conductivity and light transparency. The current injection region 5 includes, for example, a transparent electrode material such as ITO (Indium Tin Oxide).

### (9) Configurations of First Electrode 6 and Second Electrode 7

The first electrode 6 is formed on the first semiconductor layer 31 exposed by partially removing the surroundings of the epitaxial growth layer 3. The first electrode 6 is configured as an n-side metal electrode and electrically coupled to the first semiconductor layer 31.

The second electrode 7 is formed on the narrowing region 4 and on the current injection region 5. The second electrode 7 is configured as a p-side metal electrode and electrically coupled to the current injection region 5. In short, the second electrode 7 is electrically coupled to the second semiconductor layer 33 with the current injection region 5 in between.

### (10) Configuration of First Reflective Layer 8

The first reflective layer 8 is formed on the first surface 2A of the substrate 2. The first reflective layer 8 includes a curve mirror structure (a concave mirror structure) curved further downward from the first surface 2A of the substrate 2. Here, the first reflective layer 8 includes, for example, a dielectric DBR including a plurality of layers of Ta₂O₅ and a plurality of layers of SiO₂ alternately stacked on each other.

The first reflective layer 8 is disposed at a position corresponding to the above-described predetermined set value of the thickness of the epitaxial growth layer 3, i.e., a position where an offset amount of the thickness is “0” and the low threshold current density reaches the minimum value. Here, an optical axis of the first reflective layer 8 is in alignment with the position where the offset amount of the epitaxial growth layer 3 is “0.”

This allows light reflected to the epitaxial growth layer 3 with the non-uniform thickness by the first reflective layer 8 to be focused on the active layer 32. In short, it is possible to effectively reduce or prevent a diffraction loss in the surface emitting element 1.

As described above, in the surface emitting element 1, a desired difference in optical film thickness of the epitaxial growth layer 3 is set at the longitudinal mode spacing (Δλ). At the longitudinal mode spacing (Δλ), the minimum value of the low threshold current density is present.

For example, when the longitudinal mode spacing Δλ is in a range from 1.2 nm to 2.0 nm both inclusive or in a range from 1 nm to 5 nm both inclusive, it is sufficient that the difference in optical film thickness only is at least 0.5 nm, preferably exceeds 2.5 nm. Thus, a difference in optical film thickness of about 2.5 nm in optical film thickness within a predetermined region makes it possible to find an optimal film-thickness spot by, for example, measurement. Accordingly, a case where a reflective layer of a flat mirror structure (a plane mirror structure) is inclined may be considered as an embodiment. Here are a variety of examples satisfying such conditions.

1. A Case where a Substrate (Here, a Chip)*Spacing is as Small as 10 μm

In a case where a desired difference in optical film thickness is as large as 50 nm and the substrate 2 spacing is as small as 10 μm, the inclination angle is large than 0.3 degrees.

2. A Case where the Substrate 2 Spacing is as Small as 10 μm

In a case where a desired difference in optical film thickness is as small as 0.5 nm and the substrate 2 spacing is as small as 10 μm, the inclination angle is large than 0.003 degrees.

3. A Case where the Substrate 2 Spacing is in a Midrange, or 50 μm

In a case where a desired difference in optical film thickness is as small as 0.5 nm and the substrate 2 spacing is in a midrange, or 50 μm, the inclination angle is large than 0.0006 degrees.

4. A Case where the Substrate 2 Spacing is as Large as 5 cm (2 Inches)

In a case where a desired difference in optical film thickness is as small as 0.5 nm and the substrate 2 spacing is as large as 5 cm, the inclination angle is large than 6×10⁻⁷ degrees.

In short, in the above-described examples of 3. and 4., the inclination angles are allowed to be equal to or less than 0.001 degrees, so that an influence of an optical loss including a diffraction loss is almost ignorable.

The second reflective layer 9 is formed on the current injection region 5. The second reflective layer 9 includes a flat mirror structure. Here, similarly to the first reflective layer 8, the second reflective layer 9 includes a dielectric DBR.

It should be noted that at least one of the first reflective layer 8 or the second reflective layer 9 may include a semiconductor DBR.

### [Configuration of Light-Emitting Device 10]

Although illustration of an entire configuration is omitted, the light-emitting device 10 is constructed by arranging the surface emitting elements 1 illustrated in FIG. 1 in at least one of the arrow-X direction or the arrow-Y direction. The light-emitting device 10 is usable as a light source of an application device such as an optical storage, a laser printer, a projector, a display, a solid-state illuminator, an optical communication device, or a biosensor.

### [Method of Manufacturing Surface Emitting Element 1]

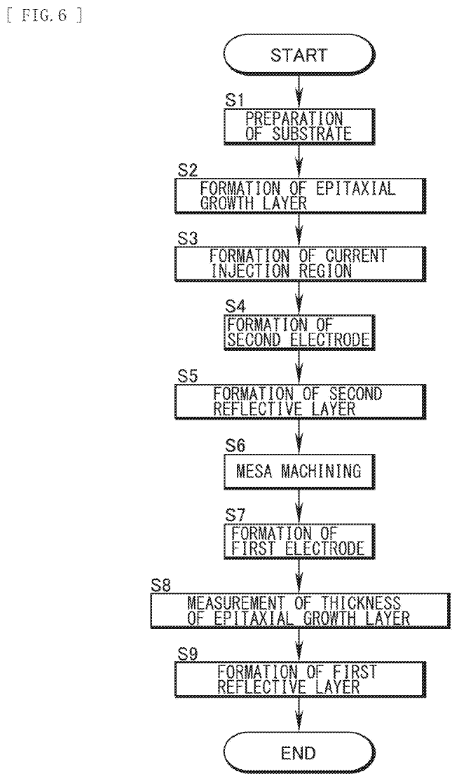

The above-described surface emitting element 1 is manufactured by the following manufacturing method. FIG. 6 illustrates a flowchart of assistance in explaining the method of manufacturing the surface emitting element 1. Steps will be briefly described below.

First, the substrate 2 is prepared (Step S1). The substrate 2 has the first surface 2A and the second surface 2B opposed to the first surface 2A.

Next, the epitaxial growth layer 3 is formed on the second surface 2B of the substrate 2 by epitaxial growth (Step S2). The epitaxial growth layer 3 is formed by sequentially stacking the first semiconductor layer 31, the active layer 32, and the second semiconductor layer 33 on one another. The epitaxial growth layer 3 has the non-uniform thickness and a distribution is formed in the resonator length of the completed surface emitting element 1.

Additionally, the narrowing region 4 is formed in the epitaxial growth layer 3.

It should be noted that a specific method of manufacturing the epitaxial growth layer 3 having a non-uniform thickness will be described in a fourth embodiment and thereafter.

Next, the current injection region 5 is formed on the second semiconductor layer 33 of the epitaxial growth layer 3 (Step S3). The current injection region 5 has light transparency, and is electrically coupled to the second semiconductor layer 33.

Subsequently, the second electrode 7 is formed on the current injection region 5 (Step S4). The second electrode 7 is electrically coupled to the second semiconductor layer 33 with the current injection region 5 in between.

Next, the second reflective layer 9 is formed on the current injection region 5 including on the second electrode 7 (Step S5). Here, the second reflective layer 9 includes a dielectric DBR.

Next, the second reflective layer 9, the current injection region 5, and a part of the epitaxial growth layer 3 are formed in a mesa shape (Step S6). The part of the epitaxial growth layer 3 is machined until a surface of the first semiconductor layer 31 becomes exposed.

Subsequently, the first electrode 6 is formed on the first semiconductor layer 31 the surface of which is exposed (Step S7). The first electrode 6 is electrically coupled to the first semiconductor layer 31.

Next, a thickness of the epitaxial growth layer 3 is measured (Step S8). Here, the thickness of the epitaxial growth layer 3 that is the predetermined set value is measured. In detail, the thickness of the epitaxial growth layer 3 at which the offset amount relative to the predetermined set value is “0” or the low threshold current density reaches the minimum value is measured.

Next, the first reflective layer 8 is formed on the first surface 2A of the substrate 2 at a position corresponding to the predetermined set value of the thickness of the epitaxial growth layer 3 (Step S9). The first reflective layer 8 includes a curve mirror structure.

When the above series of steps is done, the surface emitting element 1 according to the first embodiment is completed.

### [Workings and Effects]

The surface emitting element 1 according to the first embodiment includes the substrate 2, the epitaxial growth layer 3, the first electrode 6, the current injection region 5, the first reflective layer 8, and the second reflective layer 9 as illustrated in FIG. 1.

The substrate 2 has the first surface 2A and the second surface 2B opposed to the first surface 2A. The epitaxial growth layer 3 includes the first semiconductor layer 31 that is of the first electrically conductive type, the active layer 32, and the second semiconductor layer 33 that is of the second electrically conductive type sequentially stacked on the second surface 2B by epitaxial growth. The first electrode 6 is electrically coupled to the first semiconductor layer 31. The current injection region 5 is formed on the surface of the second semiconductor layer 33 on side opposite to the substrate 2 and is electrically coupled to the second semiconductor layer 33, and has light transparency. The first reflective layer 8 is formed on the first surface 2A. The second reflective layer 9 is formed on the surface of the current injection region 5 on side opposite to the second semiconductor layer 33.

Here, the epitaxial growth layer 3 has distributions in thickness and resonator length. Moreover, the first reflective layer 8 is formed on the first surface 2A at a position corresponding to the predetermined thickness of the epitaxial growth layer 3 and has a curve mirror structure.

This allows for formation at the thickness of the epitaxial growth layer 3 where the low threshold current density reaches the minimum value to focus light reflected by the first reflective layer 8 on the epitaxial growth layer 3. Therefore, in the surface emitting element 1, it is possible to effectively reduce or prevent an optical loss including a diffraction loss.

Additionally, in the surface emitting element 1, the stacked structure of the epitaxial growth layer 3 is uniform within the second surface 2B, which makes it possible to provide the above-described workings and effects.

Further, in the surface emitting element 1, the epitaxial growth layer 3 is formed with a non-uniform thickness within the second surface 2B, which makes it possible to provide the above-described workings and effects.

Additionally, in the surface emitting element 1, the difference in optical film thickness of the epitaxial growth layer 3 corresponds to two or more longitudinal mode spacings where the oscillation wavelength is offset, which makes it possible to provide the above-described workings and effects.

Further, in the surface emitting element 1, each of the plurality of layers in the epitaxial growth layer 3 has a distribution in thickness or the single layer in the epitaxial growth layer 3 has a distribution in thickness, which makes it possible to provide the above-described workings and effects.

Additionally, in the surface emitting element 1, the interface of the stacked structure of the epitaxial growth layer 3 is formed in a linear shape with an inclination relative to the second surface 2B in side view, which makes it possible to provide the above-described workings and effects.

Further, in the surface emitting element 1, even when the epitaxial growth layer 3 includes a material other than GaN, it is possible to provide the above-described workings and effects.

Additionally, the light-emitting device 10 includes the plurality of surface emitting elements 1 arranged. This makes it possible to effectively reduce or prevent an optical loss including a diffraction loss in the light-emitting device 10.

In addition, in the light-emitting device 10, the plurality of surface emitting elements 1 is able to output laser light beams having a plurality of wavelengths, which makes it possible to reduce speckle noise.

Further, the method of manufacturing the surface emitting element 1 includes the following steps as illustrated in FIG. 1 to FIG. 6.

The first semiconductor layer 31 that is of the first electrically conductive type, the active layer 32, and the second semiconductor layer 33 that is of the second electrically conductive type are sequentially stacked on the second surface 2B of the substrate 2 opposed to the first surface 2A by the epitaxial growth layer 3 to form the epitaxial growth layer 3 having distributions in thickness and resonator length.

The first electrode 6 is formed and the first electrode 6 is electrically coupled to the first semiconductor layer 31.

The current injection region 5 is formed on the surface of the second semiconductor layer 33 on side opposite to the substrate 2 and the current injection region 5 is electrically coupled to the second semiconductor layer 33, and has light transparency.

The second reflective layer 9 is formed on the surface of the current injection region 5 on side opposite to the second semiconductor layer 33.

The thickness of the epitaxial growth layer 3 is measured and the first reflective layer 8 having a curve mirror structure is formed on the first surface 2A at, for example, the position corresponding to the thickness of the epitaxial growth layer 3 where the threshold current density is minimized.

By virtue of including these steps, it is possible to form the surface emitting element 1 that makes it possible to effectively reduce or prevent an optical loss including a diffraction loss.

Additionally, in the surface emitting element 1, the second reflective layer 9 is allowed to be inclined as illustrated in FIG. 1. This allows the surface emitting element 1 to output a laser light beam in an oblique direction. In addition, by virtue of the second reflective layer 9 being inclined, the surface emitting element 1 is allowed to have a reflectance dependent on a polarization direction, which makes it possible to control polarization.

### 2. Second Embodiment

With use of FIG. 7, description will be made on a surface emitting element 1 and a light-emitting device 10 according to a second embodiment of the present disclosure.

It should be noted that in the second embodiment and subsequent embodiments, the same reference signs are used to refer to components that are the same or substantially the same as the components of the surface emitting element 1 and the light-emitting device 10 according to the first embodiment and redundant descriptions are omitted.

FIG. 7 schematically illustrates a vertical cross-sectional structure of the surface emitting element 1 manufactured from the epitaxial growth layer 3 in a region labeled with a reference sign B in FIG. 2 mentioned above.

In the surface emitting element 1 according to the second embodiment, a part of the interface of the stacked structure of the epitaxial growth layer 3 is formed in a linear shape with an inclination relative to the second surface 2B in side view. The other part of the interface is formed in a linear shape with no inclination relative to the second surface 2B. In short, in the surface emitting element 1, the interface of the epitaxial growth layer 3 immediately above the first reflective layer 8 may have no inclination.

Except the above-described component, the components are the same as the components of the surface emitting element 1 according to the first embodiment. Additionally, the light-emitting device 10 is constructed by arranging a plurality of surface emitting elements 1 according to the second embodiment. Further, a method of manufacturing the surface emitting element 1 is substantially the same as the method of manufacturing the surface emitting element 1 according to the first embodiment.

The surface emitting element 1, the light-emitting device 10, and the method of manufacturing the surface emitting element 1 according to the second embodiment are allowed to provide workings and effects similar to the workings and effects provided by the surface emitting element 1, the light-emitting device 10, and the method of manufacturing the surface emitting element 1 according to the first embodiment.

### 3. Third Embodiment

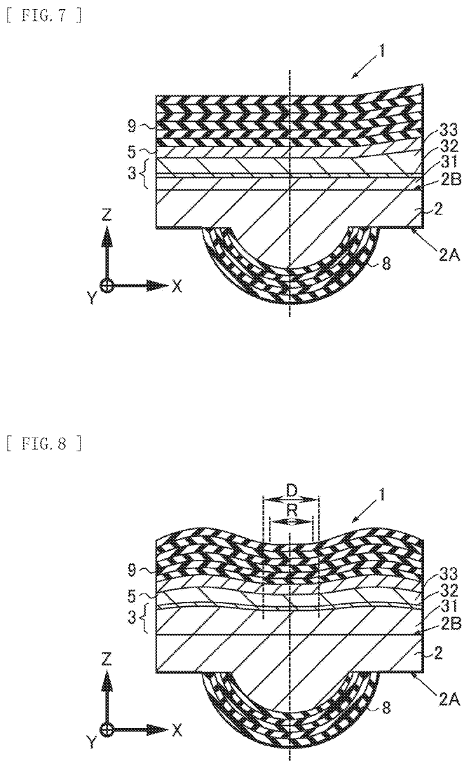

With use of FIG. 8, description will be made on a surface emitting element 1 and a light-emitting device 10 according to a third embodiment of the present disclosure.

FIG. 8 schematically illustrates a vertical cross-sectional structure of the surface emitting element 1 manufactured from the epitaxial growth layer 3 in a region labeled with a reference sign C in FIG. 2 mentioned above.

In the surface emitting element 1 according to the third embodiment, the interface of the stacked structure of the epitaxial growth layer 3 is formed in a non-linear shape in side view. In a little more detail, the surface of the epitaxial growth layer 3 has a jagged undulation.

Additionally, a width D of a flat portion of the surface of the epitaxial growth layer 3 is formed to be larger than a diameter R of a circular aperture (an opening portion) in plan view.

The meaning of the “non-linear shape” used here includes at least a shape made by combining a plurality of linear shapes with different inclinations and a curved shape.

Except the above-described component, the components are the same as the components of the surface emitting element 1 according to the first embodiment. Additionally, the light-emitting device 10 is constructed by arranging a plurality of surface emitting elements 1 according to the third embodiment. Further, a method of manufacturing the surface emitting element 1 is substantially the same as the method of manufacturing the surface emitting element 1 according to the first embodiment.

The surface emitting element 1, the light-emitting device 10, and the method of manufacturing the surface emitting element 1 according to the third embodiment are allowed to provide workings and effects similar to the workings and effects provided by the surface emitting element 1, the light-emitting device 10, and the method of manufacturing the surface emitting element 1 according to the first embodiment.

### 4. Fourth Embodiment

With use of FIG. 9, description will be made on a surface emitting element 1 and a light-emitting device 10 according to a fourth embodiment of the present disclosure. In the fourth embodiment and thereafter, description will be made on a method of manufacturing the epitaxial growth layer 3 of the surface emitting element 1.

FIG. 9 illustrates a schematic process cross section, assisting in explaining a method of manufacturing the epitaxial growth layer 3 of the surface emitting element 1.

In the method of manufacturing the epitaxial growth layer 3 of the surface emitting element 1 according to the fourth embodiment, a distribution is formed in the thickness of the epitaxial growth layer 3 by changing a temperature distribution of the substrate (the wafer) 2 during epitaxial growth. In the epitaxial growth layer 3, a growth speed usually increases with an increase in temperature. Although illustration is omitted, a growth device includes, for example, a heater positionally offset rightward to have a temperature distribution from left to right.

Except the above-described component, the components are the same as the components of the surface emitting element 1 according to the first embodiment. Additionally, the light-emitting device 10 is constructed by arranging a plurality of surface emitting elements 1 according to the fourth embodiment. Further, a method of manufacturing the surface emitting element 1 as a whole is substantially the same as the method of manufacturing the surface emitting element 1 according to the first embodiment.

The surface emitting element 1, the light-emitting device 10, and the method of manufacturing the surface emitting element 1 according to the fourth embodiment are allowed to provide workings and effects similar to the workings and effects provided by the surface emitting element 1, the light-emitting device 10, and the method of manufacturing the surface emitting element 1 according to the first embodiment.

### 5. Fifth Embodiment

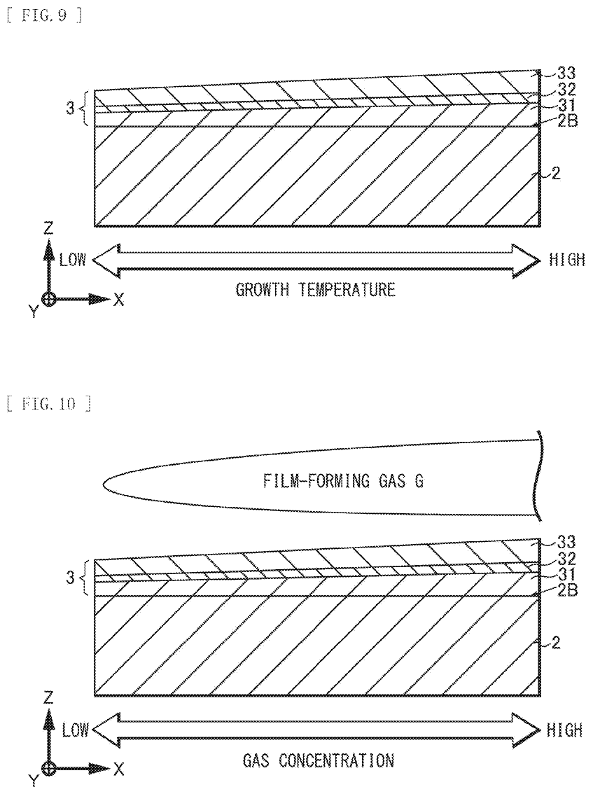

With use of FIG. 10, description will be made on a surface emitting element 1 and a light-emitting device 10 according to a fifth embodiment of the present disclosure.

FIG. 10 illustrates a schematic process cross section, assisting in explaining a method of manufacturing the epitaxial growth layer 3 of the surface emitting element 1.

In the method of manufacturing the epitaxial growth layer 3 of the surface emitting element 1 according to the fifth embodiment, a distribution is formed in the thickness of the epitaxial growth layer 3 by changing a concentration distribution of a film-forming gas G on the substrate (the wafer) 2 during epitaxial growth. In the epitaxial growth layer 3, a growth speed increases with an increase in concentration of the film-forming gas G. Although illustration is omitted, a growth device includes, for example, a supply nozzle for the film-forming gas G positionally offset rightward to have a gas concentration distribution from left to right.

Except the above-described component, the components are the same as the components of the surface emitting element 1 according to the first embodiment. Additionally, the light-emitting device 10 is constructed by arranging a plurality of surface emitting elements 1 according to the fifth embodiment. Further, a method of manufacturing the surface emitting element 1 as a whole is substantially the same as the method of manufacturing the surface emitting element 1 according to the first embodiment.

The surface emitting element 1, the light-emitting device 10, and the method of manufacturing the surface emitting element 1 according to the fifth embodiment are allowed to provide workings and effects similar to the workings and effects provided by the surface emitting element 1, the light-emitting device 10, and the method of manufacturing the surface emitting element 1 according to the first embodiment.

### 6. Sixth Embodiment

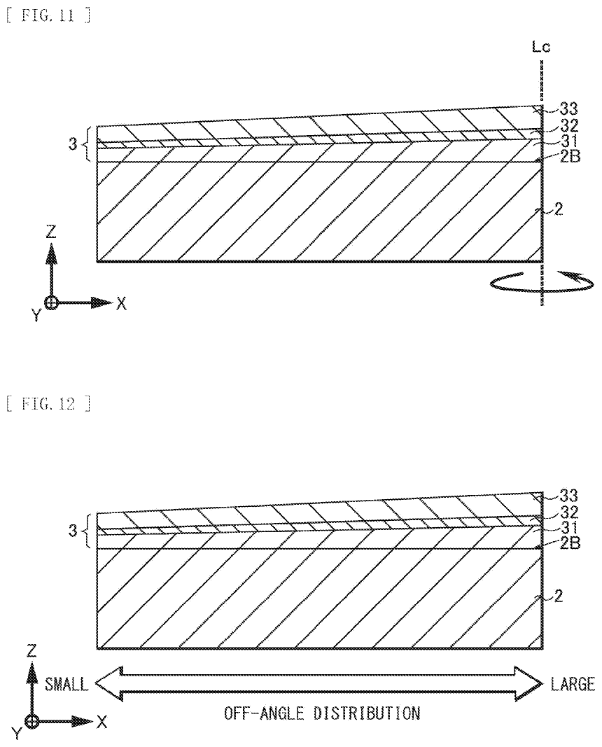

With use of FIG. 11, description will be made on a surface emitting element 1 and a light-emitting device 10 according to a sixth embodiment of the present disclosure.

FIG. 11 illustrates a schematic process cross section, assisting in explaining a method of manufacturing the epitaxial growth layer 3 of the surface emitting element 1.

In the method of manufacturing the epitaxial growth layer 3 of the surface emitting element 1 according to the sixth embodiment, a distribution is formed in the thickness of the epitaxial growth layer 3 by rotating the substrate (the wafer) 2 during epitaxial growth. For example, when a right edge of the substrate 2 is defined as a rotation center L_{C} and the substrate 2 is rotated around the rotation center L_{C}, a rotation speed of a left edge of the substrate 2 increases with respect to the right edge of the substrate 2. In short, since the temperature distribution (see FIG. 9) or the concentration distribution of the film-forming gas G (see FIG. 10) becomes low at the left edge with respect to the right edge of the substrate 2, a growth speed decreases. Although illustration is omitted, a growth device includes a mechanism that causes the substrate 2 to rotate.

Except the above-described component, the components are the same as the components of the surface emitting element 1 according to the first embodiment. Additionally, the light-emitting device 10 is constructed by arranging a plurality of surface emitting elements 1 according to the sixth embodiment. Further, a method of manufacturing the surface emitting element 1 as a whole is substantially the same as the method of manufacturing the surface emitting element 1 according to the first embodiment.

The surface emitting element 1, the light-emitting device 10, and the method of manufacturing the surface emitting element 1 according to the sixth embodiment are allowed to provide workings and effects similar to the workings and effects provided by the surface emitting element 1, the light-emitting device 10, and the method of manufacturing the surface emitting element 1 according to the first embodiment.

### 7. Seventh Embodiment

With use of FIG. 12, description will be made on a surface emitting element 1 and a light-emitting device 10 according to a seventh embodiment of the present disclosure.

FIG. 12 illustrates a schematic process cross section, assisting in explaining a method of manufacturing the epitaxial growth layer 3 of the surface emitting element 1.

In the method of manufacturing the epitaxial growth layer 3 of the surface emitting element 1 according to the seventh embodiment, a distribution is formed in the thickness of the epitaxial growth layer 3 by using the substrate (the wafer) 2 with a changed off-angle distribution during epitaxial growth. In the epitaxial growth layer 3, a growth speed increases with an increase in off-angle. Here, while the substrate 2 with a changed off-angle distribution is used, the method of manufacturing the surface emitting element 1 according to the fourth embodiment to the sixth embodiment is also used and the temperature distribution, the concentration distribution of the film-forming gas, or rotation is also used to form the epitaxial growth layer 3.

Except the above-described component, the components are the same as the components of the surface emitting element 1 according to the first embodiment. Additionally, the light-emitting device 10 is constructed by arranging a plurality of surface emitting elements 1 according to the seventh embodiment. Further, a method of manufacturing the surface emitting element 1 as a whole is substantially the same as the method of manufacturing the surface emitting element 1 according to the first embodiment.

The surface emitting element 1, the light-emitting device 10, and the method of manufacturing the surface emitting element 1 according to the seventh embodiment are allowed to provide workings and effects similar to the workings and effects provided by the surface emitting element 1, the light-emitting device 10, and the method of manufacturing the surface emitting element 1 according to the first embodiment.

### 8. Eighth Embodiment

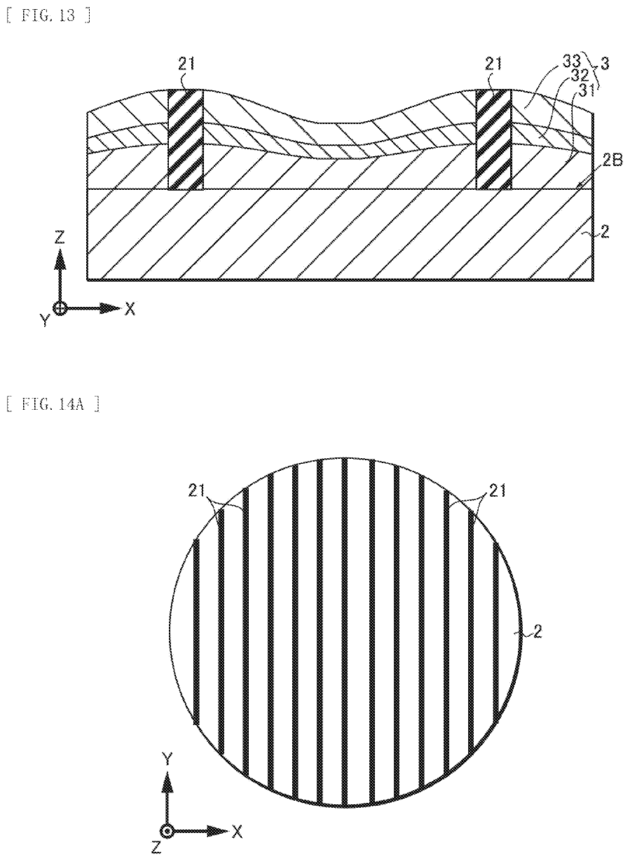

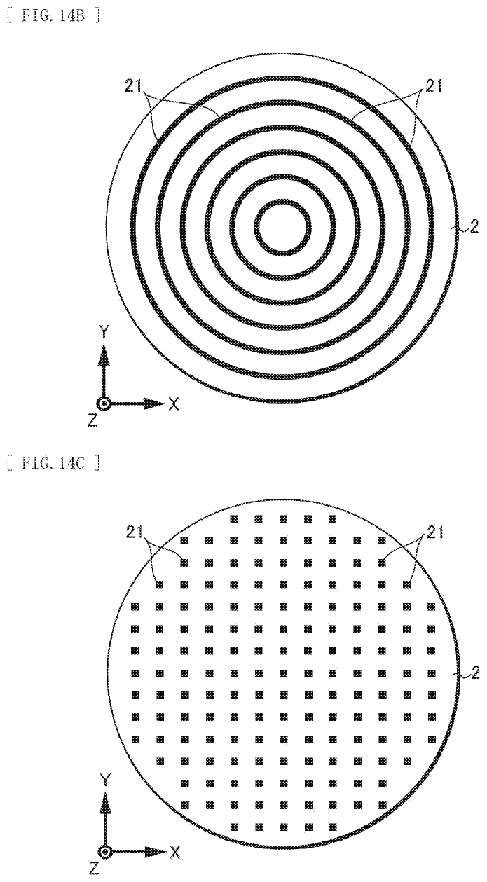

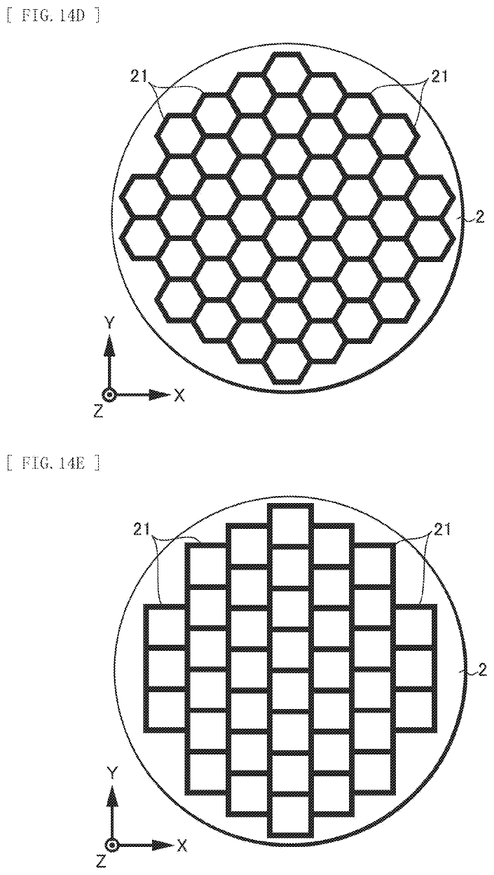

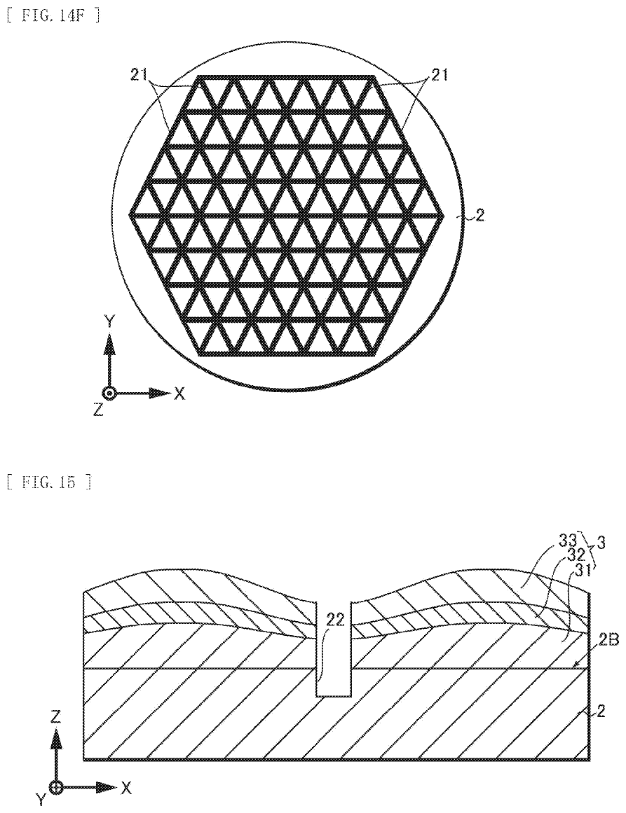

With use of FIG. 13 and FIG. 14A to FIG. 14F, description will be made on a surface emitting element 1 and a light-emitting device 10 according to an eighth embodiment of the present disclosure.

FIG. 13 illustrates a schematic process cross section, assisting in explaining a method of manufacturing the epitaxial growth layer 3 of the surface emitting element 1. FIG. 14A illustrates a planar configuration of the substrate 2 during the process illustrated in FIG. 13.

In the method of manufacturing the epitaxial growth layer 3 of the surface emitting element 1 according to the eighth embodiment, insulating bodies 21 located at a regular interval are formed on the second surface 2B of the substrate (the wafer) 2. The insulating bodies 21 are erected in the arrow-Z direction from the second surface 2B and spaced at the regular interval in the arrow-X direction, being formed in a stripe shape extending in the arrow-Y direction.

With the insulating bodies 21 formed on the substrate 2, the epitaxial growth layer 3 is formed. The epitaxial growth layer 3 is formed into a film also on side surfaces of the insulating bodies 21, thus being thickened along the side surfaces of the insulating bodies 21 and thinned at a middle between the insulating bodies 21. In short, a distribution is formed in the thickness of the epitaxial growth layer 3.

Except the above-described component, the components are the same as the components of the surface emitting element 1 according to the first embodiment. Additionally, the light-emitting device 10 is constructed by arranging a plurality of surface emitting elements 1 according to the eighth embodiment. Further, a method of manufacturing the surface emitting element 1 as a whole is substantially the same as the method of manufacturing the surface emitting element 1 according to the first embodiment.

The surface emitting element 1, the light-emitting device 10, and the method of manufacturing the surface emitting element 1 according to the eighth embodiment are allowed to provide workings and effects similar to the workings and effects provided by the surface emitting element 1, the light-emitting device 10, and the method of manufacturing the surface emitting element 1 according to the first embodiment.

### First Modification Example

FIG. 14B illustrates a planar configuration of the substrate 2 according to a first modification example of the eighth embodiment and FIG. 14B corresponds to FIG. 14A.

In a method of manufacturing the epitaxial growth layer 3 of the surface emitting element 1 according to the first modification example, insulating bodies 21 are formed in the substrate 2, the insulating bodies 21 being formed in the shape of annular rings that are concentric and have diameters increased toward a periphery of the substrate 2 in plan view. In the epitaxial growth layer 3, the insulating bodies 21 are used to form a distribution in thickness.

The surface emitting element 1, the light-emitting device 10, and the method of manufacturing the surface emitting element 1 according to the first modification example are allowed to provide workings and effects similar to the workings and effects provided by the surface emitting element 1, the light-emitting device 10, and the method of manufacturing the surface emitting element 1 according to the eighth embodiment.

### Second Modification Example

FIG. 14C illustrates a planar configuration of the substrate 2 according to a second modification example of the eighth embodiment and FIG. 14C corresponds to FIG. 14A.

In a method of manufacturing the epitaxial growth layer 3 of the surface emitting element 1 according to the second modification example, insulating bodies 21 are formed in the substrate 2, the insulating bodies 21 being formed in the shape of dots arranged in the arrow-X direction and the arrow-Y direction at regular intervals in plan view. In the epitaxial growth layer 3, the insulating bodies 21 are used to form a distribution in thickness.

The surface emitting element 1, the light-emitting device 10, and the method of manufacturing the surface emitting element 1 according to the second modification example are allowed to provide workings and effects similar to the workings and effects provided by the surface emitting element 1, the light-emitting device 10, and the method of manufacturing the surface emitting element 1 according to the eighth embodiment.

### Third Modification Example

FIG. 14D illustrates a planar configuration of the substrate 2 according to a third modification example of the eighth embodiment and FIG. 14D corresponds to FIG. 14A.

In a method of manufacturing the epitaxial growth layer 3 of the surface emitting element 1 according to the third modification example, insulating bodies 21 are formed in the substrate 2, the insulating bodies 21 being formed in the shape of hexagons (a honeycomb shape) arranged in the arrow-X direction and the arrow-Y direction at regular intervals in plan view. In the epitaxial growth layer 3, the insulating bodies 21 are used to form a distribution in thickness.

The surface emitting element 1, the light-emitting device 10, and the method of manufacturing the surface emitting element 1 according to the third modification example are allowed to provide workings and effects similar to the workings and effects provided by the surface emitting element 1, the light-emitting device 10, and the method of manufacturing the surface emitting element 1 according to the eighth embodiment.

### Fourth Modification Example

FIG. 14E illustrates a planar configuration of the substrate 2 according to a fourth modification example of the eighth embodiment and FIG. 14E corresponds to FIG. 14A.

In a method of manufacturing the epitaxial growth layer 3 of the surface emitting element 1 according to the fourth modification example, insulating bodies 21 are formed in the substrate 2, the insulating bodies 21 being formed in the shape of quadrangles (rectangles) arranged in the arrow-X direction and the arrow-Y direction at regular intervals in plan view. In the epitaxial growth layer 3, the insulating bodies 21 are used to form a distribution in thickness.

The surface emitting element 1, the light-emitting device 10, and the method of manufacturing the surface emitting element 1 according to the fourth modification example are allowed to provide workings and effects similar to the workings and effects provided by the surface emitting element 1, the light-emitting device 10, and the method of manufacturing the surface emitting element 1 according to the eighth embodiment.

### Fifth Modification Example

FIG. 14F illustrates a planar configuration of the substrate 2 according to a fifth modification example of the eighth embodiment and FIG. 14F corresponds to FIG. 14A.

In a method of manufacturing the epitaxial growth layer 3 of the surface emitting element 1 according to the fifth modification example, insulating bodies 21 are formed in the substrate 2, the insulating bodies 21 being formed in the shape of triangles arranged in the arrow-X direction and the arrow-Y direction at regular intervals in plan view. In the epitaxial growth layer 3, the insulating bodies 21 are used to form a distribution in thickness.

The surface emitting element 1, the light-emitting device 10, and the method of manufacturing the surface emitting element 1 according to the fifth modification example are allowed to provide workings and effects similar to the workings and effects provided by the surface emitting element 1, the light-emitting device 10, and the method of manufacturing the surface emitting element 1 according to the eighth embodiment.

### 9. Ninth Embodiment

With use of FIG. 15, description will be made on a surface emitting element 1 and a light-emitting device 10 according to a ninth embodiment of the present disclosure.

FIG. 15 illustrates a schematic process cross section, assisting in explaining a method of manufacturing the epitaxial growth layer 3 of the surface emitting element 1.

In the method of manufacturing the epitaxial growth layer 3 of the surface emitting element 1 according to the ninth embodiment, grooves (cores) 22 arranged at a regular interval are formed in the second surface 2B of the substrate (the wafer) 2. The grooves 22 are formed by being dug from the second surface 2B in an opposite direction to the arrow-Z direction.

The grooves 22 are formed in any of the shapes illustrated in FIG. 14A to FIG. 14F in plan view as the insulating bodies 21 according to the above-described eighth embodiment.

With the grooves 22 formed in the substrate 2, the epitaxial growth layer 3 is formed. By virtue of the presence of the grooves 22, a film formation speed decreases near the grooves 22, causing the epitaxial growth layer 3 to be thinned near the grooves 22 and thickened between the grooves 22. In short, a distribution is formed in the thickness of the epitaxial growth layer 3.

Except the above-described component, the components are the same as the components of the surface emitting element 1 according to the first embodiment. Additionally, the light-emitting device 10 is constructed by arranging a plurality of surface emitting elements 1 according to the ninth embodiment. Further, a method of manufacturing the surface emitting element 1 as a whole is substantially the same as the method of manufacturing the surface emitting element 1 according to the first embodiment.

The surface emitting element 1, the light-emitting device 10, and the method of manufacturing the surface emitting element 1 according to the ninth embodiment are allowed to provide workings and effects similar to the workings and effects provided by the surface emitting element 1, the light-emitting device 10, and the method of manufacturing the surface emitting element 1 according to the eighth embodiment.

### 10. Other Embodiments

The present technology is not limited to the above-described embodiments and may be modified in various manners without departing from the gist thereof.

For example, in the present technology, two or more of the surface emitting elements according to the above-described plurality of embodiments and plurality of modification examples may be combined.

A surface emitting element according to the first embodiment of the present disclosure includes a substrate, an epitaxial growth layer, a first electrode, a current injection region, a first reflective layer, and a second reflective layer.

The substrate has a first surface and a second surface opposed to the first surface. The epitaxial growth layer includes a first semiconductor layer that is of a first electrically conductive type, an active layer, and a second semiconductor layer that is of the second electrically conductive type sequentially stacked on the second surface by epitaxial growth. The first electrode is electrically coupled to the first semiconductor layer. The current injection region is formed on a surface of the second semiconductor layer on side opposite to the substrate and is electrically coupled to the second semiconductor layer, and has light transparency. The first reflective layer is formed on the first surface. The second reflective layer is formed on a surface of the current injection region on side opposite to the second semiconductor layer.

Here, the epitaxial growth layer has distributions in thickness and resonator length. Moreover, the first reflective layer is formed on the first surface at a position corresponding to a predetermined thickness of the epitaxial growth layer and has a curve mirror structure.

This allows for formation at the thickness of the epitaxial growth layer where a low threshold current density reaches a minimum value to focus light reflected by the first reflective layer on the epitaxial growth layer. Therefore, it is possible to effectively reduce or prevent an optical loss including a diffraction loss in the surface emitting element.

Additionally, a light-emitting device according to the second embodiment of the present disclosure includes a plurality of surface emitting elements arranged. This makes it possible to effectively reduce or prevent an optical loss including a diffraction loss in the light-emitting device.

Further, a method of manufacturing the surface emitting element according to the third embodiment of the present disclosure includes the following steps.

The first semiconductor layer that is of the first electrically conductive type, the active layer, and the second semiconductor layer that is of the second electrically conductive type are sequentially stacked on the second surface of the substrate opposed to the first surface by the epitaxial growth layer to form the epitaxial growth layer having distributions in thickness and resonator length.

The first electrode electrically coupled to the first semiconductor layer is formed.

The current injection region is formed on the surface of the second semiconductor layer on side opposite to the substrate, the current injection region being electrically coupled to the second semiconductor layer and having light transparency.

The second reflective layer is formed on the surface of the current injection region on side opposite to the second semiconductor layer.

The thickness of the epitaxial growth layer is measured and the first reflective layer having a curve mirror structure is formed at a predetermined position in the first surface.

By virtue of including these steps, it is possible to form a surface emitting element that makes it possible to effectively reduce or prevent an optical loss including a diffraction loss.

### <Configuration of Present Technology>

The present technology includes the following configuration. By virtue of the present technology having the following configuration, it is possible to provide a surface emitting element, a light-emitting device, and a method of manufacturing a surface emitting element each of which makes it possible to effectively reduce or prevent an optical loss including a diffraction loss.

(1)

A surface emitting element including:
a substrate having a first surface and a second surface opposed to the first surface;
an epitaxial growth layer including a first semiconductor layer that is of a first electrically conductive type, an active layer, and a second semiconductor layer that is of a second electrically conductive type sequentially stacked on the second surface by epitaxial growth, the epitaxial growth layer having distributions in thickness and resonator length;
an electrode electrically coupled to the first semiconductor layer;
a current injection region formed on a surface of the second semiconductor layer on side opposite to the substrate, the current injection region being electrically coupled to the second semiconductor layer and having light transparency;
a first reflective layer formed on the first surface at a position corresponding to a predetermined thickness of the epitaxial growth layer, the first reflective layer including a curve mirror structure; and
a second reflective layer formed on a surface of the current injection region on side opposite to the second semiconductor layer.
   (2)

The surface emitting element according to (1), in which a stacked structure of the epitaxial growth layer is uniform within the second surface.

(3)

The surface emitting element according to (1) or (2), in which the epitaxial growth layer has the distributions in thickness and resonator length within the second surface.

(4)

The surface emitting element according to any one of (1) to (3), in which a difference in optical film thickness of the epitaxial growth layer corresponds to an adjacent longitudinal mode spacing or more.

(5)

The surface emitting element according to any one of (1) to (4), in which each of a plurality of layers in the epitaxial growth layer has the distribution in thickness.

(6)

The surface emitting element according to any one of (1) to (4), in which a single layer in the epitaxial growth layer has the distribution in thickness.

(7)

The surface emitting element according to any one of (1) to (6), in which an interface of a stacked structure of the epitaxial growth layer is formed in a linear shape with an inclination relative to the second surface as viewed from a plane direction of the second surface.

(8)

The surface emitting element according to any one of (1) to (6), in which a part of an interface of a stacked structure of the epitaxial growth layer is formed in a linear shape with an inclination relative to the second surface as viewed from a plane direction of the second surface.

(9)

The surface emitting element according to any one of (1) to (6), in which an interface of a stacked structure of the epitaxial growth layer is formed in a non-linear shape as viewed from a plane direction of the second surface.

(10)

The surface emitting element according to (9), in which
a surface of the epitaxial growth layer has an undulation as viewed from the plane direction of the second surface, and
a width of a flat portion of the surface of the epitaxial growth layer is larger than a diameter of an aperture.
   (11)

The surface emitting element according to any one of (1) to (10), in which the epitaxial growth layer includes at least one or more materials selected from among GaN, InGaN, AlGaN, AlGaInN, GaAs, AlGaAs, AlAs, InGaAs, AlInGaP, InGaP, InP, InAlAs, AlInGaAs, AlGaAsP, InGaAs, InGaSb, and AlGaSb.

(12)

A light-emitting device including a plurality of surface emitting elements arranged, the surface emitting elements each including
a substrate having a first surface and a second surface opposed to the first surface,
an epitaxial growth layer including a first semiconductor layer that is of a first electrically conductive type, an active layer, and a second semiconductor layer that is of a second electrically conductive type sequentially stacked on the second surface by epitaxial growth, the epitaxial growth layer having distributions in thickness and resonator length,
an electrode electrically coupled to the first semiconductor layer,
a current injection region formed on a surface of the second semiconductor layer on side opposite to the substrate, the current injection region being electrically coupled to the second semiconductor layer and having light transparency,
a first reflective layer formed on the first surface at a position corresponding to a predetermined thickness of the epitaxial growth layer, the first reflective layer including a curve mirror structure, and
a second reflective layer formed on a surface of the current injection region on side opposite to the second semiconductor layer.
   (13)

A method of manufacturing a surface emitting element, the method including:
forming an epitaxial growth layer having distributions in thickness and resonator length by sequentially stacking, on a second surface, opposed to a first surface, of a substrate, a first semiconductor layer that is of a first electrically conductive type, an active layer, and a second semiconductor layer that is of a second electrically conductive type by epitaxial growth;
forming an electrode electrically coupled to the first semiconductor layer;
forming a current injection region on a surface of the second semiconductor layer on side opposite to the substrate, the current injection region being electrically coupled to the second semiconductor layer and having light transparency;
forming a second reflective layer on a surface of the current injection region on side opposite to the second semiconductor layer; and
measuring a thickness of the epitaxial growth layer and forming a first reflective layer including a curve mirror structure at a predetermined position in the first surface.

The present application claims the benefit of Japanese Priority Patent Application JP2021-145937 filed with the Japan Patent Office on Sep. 8, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A surface emitting element comprising:
a substrate having a first surface and a second surface opposed to the first surface;
an epitaxial growth layer including a first semiconductor layer that is of a first electrically conductive type, an active layer, and a second semiconductor layer that is of a second electrically conductive type sequentially stacked on the second surface by epitaxial growth, the epitaxial growth layer having distributions in thickness and resonator length;
an electrode electrically coupled to the first semiconductor layer;
a current injection region formed on a surface of the second semiconductor layer on side opposite to the substrate, the current injection region being electrically coupled to the second semiconductor layer and having light transparency;
a first reflective layer formed on the first surface at a position corresponding to a predetermined thickness of the epitaxial growth layer, the first reflective layer including a curve mirror structure; and
a second reflective layer formed on a surface of the current injection region on side opposite to the second semiconductor layer.

2. The surface emitting element according to claim 1, wherein a stacked structure of the epitaxial growth layer is uniform within the second surface.

3. The surface emitting element according to claim 1, wherein the epitaxial growth layer has the distributions in thickness and resonator length within the second surface.

4. The surface emitting element according to claim 1, wherein a difference in optical film thickness of the epitaxial growth layer corresponds to an adjacent longitudinal mode spacing or more.

5. The surface emitting element according to claim 1, wherein each of a plurality of layers in the epitaxial growth layer has the distribution in thickness.

6. The surface emitting element according to claim 1, wherein a single layer in the epitaxial growth layer has the distribution in thickness.

7. The surface emitting element according to claim 1, wherein an interface of a stacked structure of the epitaxial growth layer is formed in a linear shape with an inclination relative to the second surface as viewed from a plane direction of the second surface.

8. The surface emitting element according to claim 1, wherein a part of an interface of a stacked structure of the epitaxial growth layer is formed in a linear shape with an inclination relative to the second surface as viewed from a plane direction of the second surface.

9. The surface emitting element according to claim 1, wherein an interface of a stacked structure of the epitaxial growth layer is formed in a non-linear shape as viewed from a plane direction of the second surface.

10. The surface emitting element according to claim 9, wherein
a surface of the epitaxial growth layer has an undulation as viewed from the plane direction of the second surface, and
a width of a flat portion of the surface of the epitaxial growth layer is larger than a diameter of an aperture.

11. The surface emitting element according to claim 1, wherein the epitaxial growth layer includes at least one or more materials selected from among GaN, InGaN, AlGaN, AlGaInN, GaAs, AlGaAs, AlAs, InGaAs, AlInGaP, InGaP, InP, InAlAs, AlInGaAs, AlGaAsP, InGaAs, InGaSb, and AlGaSb.

12. A light-emitting device comprising a plurality of surface emitting elements arranged, the surface emitting elements each including
a substrate having a first surface and a second surface opposed to the first surface,
an epitaxial growth layer including a first semiconductor layer that is of a first electrically conductive type, an active layer, and a second semiconductor layer that is of a second electrically conductive type sequentially stacked on the second surface by epitaxial growth, the epitaxial growth layer having distributions in thickness and resonator length,
an electrode electrically coupled to the first semiconductor layer,
a current injection region formed on a surface of the second semiconductor layer on side opposite to the substrate, the current injection region being electrically coupled to the second semiconductor layer and having light transparency,
a first reflective layer formed on the first surface at a position corresponding to a predetermined thickness of the epitaxial growth layer, the first reflective layer including a curve mirror structure, and
a second reflective layer formed on a surface of the current injection region on side opposite to the second semiconductor layer.

13. A method of manufacturing a surface emitting element, the method comprising:
forming an epitaxial growth layer having distributions in thickness and resonator length by sequentially stacking, on a second surface, opposed to a first surface, of a substrate, a first semiconductor layer that is of a first electrically conductive type, an active layer, and a second semiconductor layer that is of a second electrically conductive type by epitaxial growth;
forming an electrode electrically coupled to the first semiconductor layer;
forming a current injection region on a surface of the second semiconductor layer on side opposite to the substrate, the current injection region being electrically coupled to the second semiconductor layer and having light transparency;
forming a second reflective layer on a surface of the current injection region on side opposite to the second semiconductor layer; and
measuring a thickness of the epitaxial growth layer and forming a first reflective layer including a curve mirror structure at a predetermined position in the first surface.
